(19) United States
(12) Patent Application Publication
(10) Pub. No.: US 2025/0324813 A1
(43) Pub. Date: Oct. 16, 2025

(54) CIRCULAR INTERDIGITAL ARRAY PLASMON ELECTRODE PHOTOELECTRIC DETECTOR SUITABLE FOR NON-POLARIZED LIGHT AND PREPARATION METHOD FOR THE SAME

(71) Applicant: GUANGDONG UNIVERSITY OF TECHNOLOGY, Guangdong (CN)

(72) Inventors: Wenjie LIU, Guangdong (CN); Yuhang GUO, Guangdong (CN); Haobin ZHONG, Guangdong (CN); Yuwen LANG, Guangdong (CN); Kaixiang FU, Guangdong (CN); Yuwen QIN, Guangdong (CN); Yuncai WANG, Guangdong (CN)

(73) Assignee: GUANGDONG UNIVERSITY OF TECHNOLOGY, Guangdong (CN)

(21) Appl. No.: 19/250,098

(22) Filed: Jun. 26, 2025

Related U.S. Application Data
(63) Continuation of application No. PCT/CN2024/121474, filed on Sep. 26, 2024.

(30) Foreign Application Priority Data
Dec. 19, 2023 (CN) 202311756149.8

(51) Int. Cl. H10F 77/20; H10F 30/221; H10F 30/227; H10F 71/00; H10F 77/30

(52) U.S. Cl. CPC H10F 77/241; H10F 30/2215; H10F 30/227; H10F 71/1272; H10F 77/306

(57) ABSTRACT

Disclosed is a circular interdigital array plasmon electrode photoelectric detector suitable for non-polarized light. The detector includes a substrate, a semiconductor layer and a circular interdigital array electrode, where rectangular electrodes on left side and right side of the circular interdigital array electrode respectively form a positive electrode and a negative electrode, the positive and negative electrodes are connected to the circular interdigital array electrode through electrode connecting wires, and a circular electrode array and the electrode connecting wires form a circular interdigital array electrode structure. A preparation method for a circular interdigital array plasmon electrode photoelectric detector is also provided. According to the present disclosure, by adjusting inner circle and outer circle radii and the arrangement manner of circular electrodes, the polarization-insensitive effect of the detector for incident light is achieved, and the absorption efficiency for the incident light and the bandwidth of the detector are increased.

### CROSS-REFERENCE TO RELATED APPLICATIONS

This application is a continuation of international PCT application No. PCT/CN2024/121474, filed on Sep. 26, 2024, which claims the priority benefit of Chinese patent application No. 202311756149.8, filed on Dec. 19, 2023. The entirety of each of the above-mentioned patent applications is hereby incorporated by reference herein and made a part of this specification.

### TECHNICAL FIELD

The present disclosure belongs to the technical field of photoelectric devices, and mainly relates to a plasmon electrode photoelectric detector structure suitable for non-polarized light.

### BACKGROUND

Photoelectric detectors are devices that can convert optical signals into electric signals by utilizing the photoelectric effect, and are widely used. According to different working wavebands, the detectors can be divided into infrared photoelectric detectors, visible-light photoelectric detectors, and ultraviolet photoelectric detectors. The most common infrared photoelectric detectors are widely used in important fields such as infrared imaging, night-vision devices, space exploration, security inspection and biomedicine, leading to extremely active research on infrared detectors. Various materials can be chosen to be used for the infrared detectors, for example, HgCdTe, InGaAs, GaAs, Si, and the like. A GaAs semiconductor material has the advantages of direct bandgap, high electron mobility, high-temperature resistance, low power, broad absorption spectrum from ultraviolet light to near-infrared light; an InGaAs material can be used to detect incident light in a range of 1-3 μm by changing an InP component, has the advantages of mature technological level, small detection volume, and the like, and is therefore widely used in the field of optical detection. However, such photoelectric detectors still have many defects and the problems of low adsorption efficiency of semiconductor materials, low photoelectric conversion efficiency, small device bandwidth, and the like.

Recent research indicates that by using the surface plasmon phenomenon generated by a metal nanostructure under light irradiation, an optical field can be localized on a surface of the metal structure, and the great field enhancement can be obtained. The response performance of the photoelectric detectors can be effectively improved. However, the photoelectric detectors based on interdigital and grating structures greatly rely on polarization of the incident light, which is also a main problem that limits the development of the detectors.

For example, the stimulation from an external environment makes a semiconductor laser and an optical fiber laser undergo polarization change; besides, when an optical fiber is coupled with an ordinary single-mode optical fiber, consistent polarization cannot be maintained; in addition, an ASE broadband light source is subjected to shaping filtering through an optical filter, then a filtered spectrum is input into a high-speed photoelectric detector, millimeter wave noise can be obtained, and it is difficult to control the polarization direction of light output by the broadband light source; and the detector suitable for different polarization incident light can increase the absorption efficiency for the incident light and increase the output power.

Therefore, it is very important to develop a photoelectric detector suitable for non-polarized light.

### SUMMARY

The present disclosure aims to provide a circular interdigital array electrode photoelectric detector structure suitable for non-polarized light. A circular interdigital array electrode can excite the localized surface plasmon effect without relying on polarization of incident laser light, so that the problems that a photoelectric detector using a grating-structure electrode is sensitive to polarization of incident light and low in absorption efficiency are solved. Meanwhile, under the condition of the same transport distance of the carrier, the capacitance of an active region of the detector is reduced, the dark current is reduced, and the RC (Resistor-Capacitance circuit) bandwidth of the detector is increased, thereby increasing the overall bandwidth of the detector.

On the basis of the above purposes, the present disclosure adopts the following technical solution:
a plasmon electrode photoelectric detector suitable for non-polarized light, including: a substrate, a semiconductor layer, an electrode layer, and an anti-reflection layer, where the electrode layer includes a circular interdigital array electrode and positive and negative electrodes on left and right sides; the circular interdigital array electrode includes circular electrodes and circular electrode connecting wires.

Further, the circular electrodes of the circular interdigital array electrode are connected through and are placed between the positive and negative electrodes; and a circular electrode array may be classified into a staggered distribution type and an aligned distribution type according to different arrangement manners.

Further, the electrode layer is in ohmic contact or Schottky contact with the semiconductor layer; and under the action of an incident light field, free electrons on surfaces of metal electrodes of the circular interdigital array electrode structure are excited, and when plasmon resonance conditions are met, local electric field enhancement is generated around the metal electrodes, the absorption efficiency of the semiconductor layer for incident light is increased, and thus the responsivity is improved.

Further, the circular electrodes of the circular interdigital array electrode are electrically connected to the positive and negative electrodes on the left and right sides through the circular electrode connecting wires, each row of the circular electrodes have reverse polarity to polarity of adjacent rows of the circular electrodes, and when incident light in different polarization directions irradiates the detector, the absorptivity of the semiconductor layer remains stable.

Further, for a staggered distribution type structure, minimum distances between any circle and adjacent circles around are equal to each other, and distances between the adjacent circles are reduced to shorten a transport distance and increase a carrier transport bandwidth of the detector; and for an aligned distribution type structure, the circles are arranged in a regular rectangular array, and distances between every two adjacent rows are reduced to shorten the transport distance and increase the transport bandwidth.

Further, a material of the electrode layer is Ti, Al, Ni, Ge, Au, or Ag, or an alloy of Ti, Al, Ni, Ge, Au, Ag.

Further, a material of the semiconductor layer is made of GaAs, InGaAs, an InGaAs/InAlAs superlattice material, ErAs:In(Al)GaAs, or the like.

Further, a material of the anti-reflection film is made of SiNx, SiOx, or the like.

In addition, the present disclosure further provides a preparation method for a circular interdigital array plasmon electrode photoelectric detector suitable for non-polarized light, including the following steps:
step 1: growing an epitaxial layer on a temporary substrate by using a metal-organic chemical vapor deposition or molecular beam epitaxy method;
step 2: performing photoetching, primary metal evaporation and metal stripping on a surface of the epitaxial layer to form a circular array electrode, electrode connecting wires, and positive and negative electrodes on left and right sides;
step 3: performing photoetching and etching on the structure to form a mesa structure, thereby obtaining a mesa semiconductor epitaxial layer, where an upper surface of the semiconductor epitaxial layer is covered with a metal electrode layer obtained in step 2; and
step 4: performing photoetching and metal evaporation to form coplanar waveguide electrodes in contact with the positive and negative electrodes on the left and right sides, thereby forming an electric connection for wire bonding during subsequent packaging.

The present disclosure provides a plasmon electrode photoelectric detector structure suitable for non-polarized light. From bottom to top, the plasmon electrode photoelectric detector structure includes: a substrate arranged at the bottom, where the substrate may be made of a semiconductor material with the relatively high heat conductivity, such as Si, InP, GaAs, or the like; a semiconductor layer arranged above the substrate, where when the semiconductor layer is irradiated by light and energy of the incident light is greater than an energy gap of the material of the semiconductor layer, a semiconductor absorbs photon energy to generate electron-hole pairs, and photo-generated carriers are transported to electrodes on two sides under an externally applied biased electric field, thereby collecting and forming light currents at the electrodes; and as a further definition, the material of the semiconductor layer may be a semiconductor material such as GaAs, InGaAs, an InGaAs/InAlAs superlattice material, ErAs:In(Al)GaAs, or the like; and
an electrode layer arranged above the semiconductor layer and including a circular electrode array, positive and negative electrodes on left and right sides, and electrode connecting wires, where the electrode layer is in ohmic contact or Schottky contact with the semiconductor layer; the circular electrode array and the electrode connecting wires are arranged between the positive and negative electrodes on the left and right sides; the circular electrode array is arranged as per a specific cycle; each row of circular structures are the same in quantity; two distribution types may be formed and respectively include: an aligned distribution type, that is, each row of circular electrodes are arranged to be aligned with adjacent rows of the circular electrodes; and a staggered distribution type, that is, each row of circular electrodes are arranged to be staggered with adjacent rows of the circular electrodes; the circular electrodes in each row are connected through the electrode connecting wires and are connected to the positive electrode or the negative electrode on one side, and the circular electrodes in the adjacent rows are connected to rectangular electrodes on different sides respectively.

Under the action of the incident light, free electrons on a surface of the metal nanostructure are excited, when the light interacts with the free electrons and at the frequency consistent with that of the free electrons, a resonance phenomenon is generated, and such phenomenon, where surface plasmons are localized on the surface around the metal nanostructure, is known as localized surface plasmon resonance (LSPR); and the circular structures can localize the incident light in different polarization directions on internal metal surfaces thereof and generate field enhancement, which can greatly improve the absorption of the semiconductor layer for the incident light.

To improve the bandwidth performance of the detector, the bandwidth of the detector is mainly determined by two variables, which are respectively carrier transport time and an RC time constant, and the formula of the bandwidth of the detector may be represented as:

$${f}_{3 db} = \frac{1}{2 π \sqrt{{τ}_{trans}^{2} + {τ}_{RC}^{2}}}$$

where τₜᵣₐₙₛ is the carrier transport time, and ⊖_{RC} is the RC time constant.

For the same material, the carrier transport time is determined by a transport distance, when the electrode transport distance is reduced, the carrier transport time may be shortened, but the reduction of the electrode distance may cause the increase of the capacitance of an active region of the detector, resulting in the increase of the RC time constant. Therefore, there is a restrictive relationship between the reduction of the transport distance and the increase of the bandwidth.

The RC time constant is related to the capacitance of the active region of the detector, and for the interdigital electrode type detector, through the qualitative analysis, a capacitance formula thereof can be represented as:

$$C = \frac{K ( k )}{K ( {k}^{′} )} {ε}_{0} ( 1 + {ε}_{r} ) \frac{A}{P}$$

where εᵣ is a relative dielectric constant of a semiconductor, A is a detection area of the detector, P is a period of an interdigital electrode, and K(k) is a complete elliptic integral of the first kind,

$$\begin{matrix}K ( k ) = {\int }_{0}^{π / 2} \frac{d φ}{\sqrt{( 1 - {k}^{2} {sin}^{2} φ )}} \\ k = {tan}^{2} ( \frac{π w}{4 P} ) \\ {k}^{′} = \sqrt{1 - {k}^{2}}\end{matrix}$$

where w is an electrode width, and the ratio of w to P is a duty ratio of the interdigital electrode; and it can be seen from the formula that when other variables remain constant, the larger the duty ratio, the greater the capacitance of the detector.

Compared with a traditional interdigital electrode structure, the circular interdigital array electrode provided by the present disclosure has the advantages that under the conditions of the same interdigital length and the same transport distance of the carrier, the average duty ratio of the circular interdigital array electrode is less than that of the interdigital electrode, so that the smaller active region capacitance can be obtained, and the bandwidth of the detector is increased.

A material of the electrode layer may be one of Ti, Al, Ni, Ge, Au, Cr and other high-conductivity metals or may be a combination of several of Ti, Al, Ni, Ge, Au, Cr and other high-conductivity metals.

The positive and negative electrodes on the left and right sides are externally connected to a positive electrode on one side and are externally connected to a negative electrode on the other side, thereby applying a bias voltage to the detector.

The anti-reflection film covers on the semiconductor and the electrode layer, and a material of the anti-reflection film is a dielectric material such as silicon nitride, silicon dioxide, or the like.

The present disclosure has the following advantages and beneficial technical effects:
1) the plasmon electrode photoelectric detector suitable for non-polarized light provided by the present disclosure achieves stable absorption of the semiconductor layer of the photoelectric detector in the different incident light polarization directions, improves the absorptivity, and achieves the effect of increasing the response bandwidth of the detector;
2) the present disclosure provides the circular array electrode structure, the circular structures in each row are connected through the electrode connecting wires, and the adjacent rows are electrically connected to the positive and negative electrodes alternately, thereby forming the positive-negative-positive electrode arrangement form; compared with the traditional interdigital electrode, the distances between the every two adjacent rows of circular electrodes are shortened to reduce the carrier transport distance, reduce the carrier transit time, and increase the transport bandwidth of the detector; however, the reduction of the distances between the electrodes may cause the increase of the capacitance of the active region, thereby affecting the RC bandwidth; and the electrode length under the minimum transport distance can be effectively reduced through the circular array structure, the reduction of the RC bandwidth is avoided under the same area of the active region, and the response bandwidth of the detector is increased; and
3) the circular array electrode provided by the present disclosure is arranged in a certain cycle, and it is verified through analogue simulation that the circular array electrode has the advantage of being insensitive to polarization of the incident light; and under the action of a light field, an electrode-semiconductor layer interface forms local field enhancement and increases the absorption efficiency of the semiconductor layer for the incident light, so that the electrode collects more photo-generated carriers, and the photoelectric conversion efficiency of the detector is improved.

### BRIEF DESCRIPTION OF DRAWINGS

Drawings herein are incorporated into the description and constitute a portion of the description, show embodiments conforming to the present disclosure, and are used for explaining principles of the present disclosure together with the description.

FIG. 1 is a central section schematic diagram of a unit structure in a photoelectric detector structure for non-polarized light provided in the present disclosure.

FIG. 2 is a top view of the unit structure in the photoelectric detector structure for non-polarized light provided in the present disclosure.

FIG. 3 is a top view of a staggered distribution type structure of the photoelectric detector structure for non-polarized light provided in the present disclosure.

FIG. 4 is a top view of an aligned distribution type structure of the photoelectric detector structure for non-polarized light provided in the present disclosure.

FIG. 5 is a curve chart of light absorptivity of semiconductor layers of the photoelectric detector structure for non-polarized light provided in the present disclosure and of an interdigital electrode structure changing with polarization directions.

FIG. 6 is a section electric field schematic diagram of the unit structure in the photoelectric detector structure for non-polarized light provided in the present disclosure.

FIG. 7 shows the influence on the bandwidth of the photoelectric detector structure for non-polarized light provided in the present disclosure with carrier transport time, and the relationship between a bandwidth difference Δf of two detector structures and the carrier transport time.

Description of reference numerals in the drawings:
1: anti-reflection layer of the photoelectric detector structure for non-polarized light; 2: electrode layer of the photoelectric detector structure for non-polarized light; 3: semiconductor layer of the photoelectric detector structure for non-polarized light; 4: substrate of the photoelectric detector structure for non-polarized light; 5: circular electrode in the electrode layer of the photoelectric detector structure for non-polarized light; 6: electrode connecting wire in the electrode layer of the photoelectric detector structure for non-polarized light.

### DETAILED DESCRIPTION OF EMBODIMENTS

In order to make the purpose, technical solutions and advantages of the present disclosure clearer, the present disclosure is further described in detail in conjunction with the specific embodiments and with reference to the accompanying drawings below.

The present disclosure discloses a plasmon electrode photoelectric detector structure suitable for non-polarized light and a preparation method therefor. The detector structure includes: a substrate at the bottom; a semiconductor layer arranged above the substrate; a circular interdigital array electrode arranged above the semiconductor layer, where the circular interdigital array electrode is electrically connected through electrode connecting wires between an array; and rectangular electrodes arranged on left and right sides of the circular interdigital array electrode, where the rectangular electrodes on the two sides respectively form a positive electrode and a negative electrode of the detector and are used to apply a bias voltage to the detector, the positive and negative electrodes on the two sides are connected to the circular interdigital array electrode through the electrode connecting wires, and a circular electrode array and the electrode connecting wires form a circular interdigital array electrode structure.

According to the circular interdigital array electrode-based photoelectric detector structure suitable for non-polarized light provided in the present disclosure, by adjusting an outer circle radius and an inner circle radius of each of the circular electrodes and the arrangement manner of circular electrodes, the polarization-insensitive effect of the detector for incident light is achieved, and the absorption efficiency for the incident light and the bandwidth of the detector are increased.

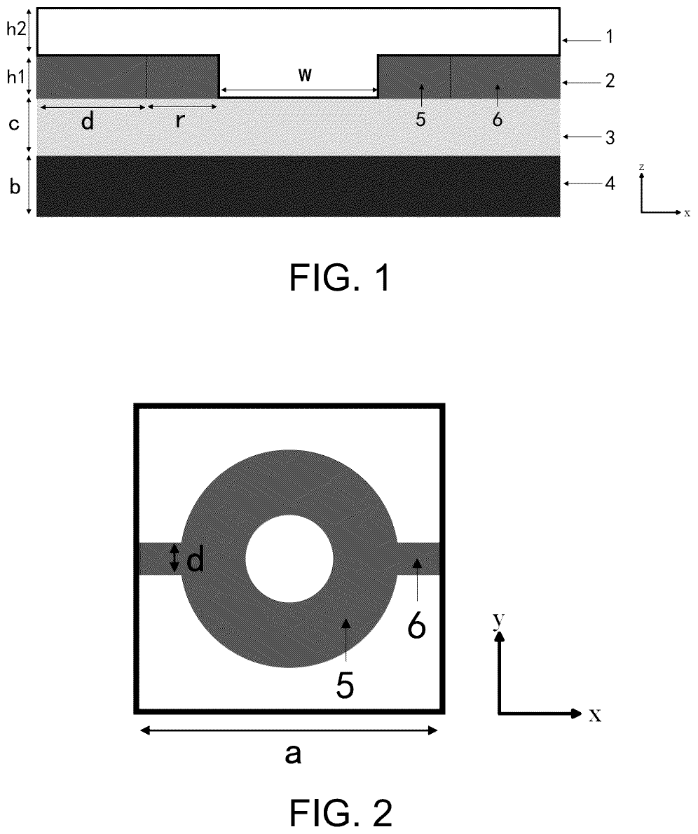

FIG. 1 is a central section schematic diagram of a unit structure in the photoelectric detector structure for non-polarized light provided according to an exemplary embodiment. With reference to FIG. 1, the embodiment of the present disclosure provides the photoelectric detector structure for non-polarized light, including: an anti-reflection layer 1 of the photoelectric detector structure for non-polarized light, an electrode layer 2 of the photoelectric detector structure for non-polarized light, a semiconductor layer 3 of the photoelectric detector structure for non-polarized light, a substrate 4 of the photoelectric detector structure for non-polarized light, circular electrodes 5 in the electrode layer of the photoelectric detector structure for non-polarized light, and electrode connecting wires in the electrode layer of the photoelectric detector structure for non-polarized light. The anti-reflection layer 1 of the photoelectric detector structure for non-polarized light is arranged above the electrode layer 2 and the semiconductor layer 3 and is configured to increase transmission of incident light and reduce reflection. The electrode layer 2 is arranged between the anti-reflection layer 1 and the semiconductor layer 3 and includes a circular interdigital array electrode and positive and negative electrodes on left and right sides, and a circular interdigital array electrode includes the circular electrodes 5 and the electrode connecting wires 6.

The semiconductor layer 3 is arranged between the electrode layer 2 and the substrate 4, is configured to absorb the incident light, and generates photo-generated electron-hole pairs therein, under the action of an external bias voltage, electrons drift towards the positive electrode while holes drift towards the negative electrode, and the photo-generated electron-hole pairs are collected by the electrode and form light currents for output.

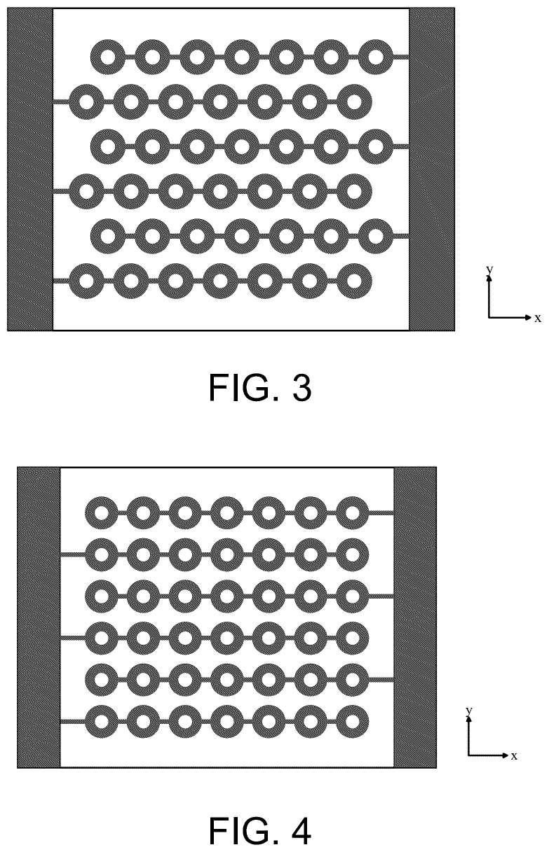

FIG. 2 is a top view of the unit structure in the photoelectric detector structure for non-polarized light provided in the present disclosure.

FIG. 3 is a top view of a staggered distribution type structure of the photoelectric detector structure for non-polarized light provided in the present disclosure.

FIG. 4 is a top view of an aligned distribution type structure of the photoelectric detector structure for non-polarized light provided in the present disclosure.

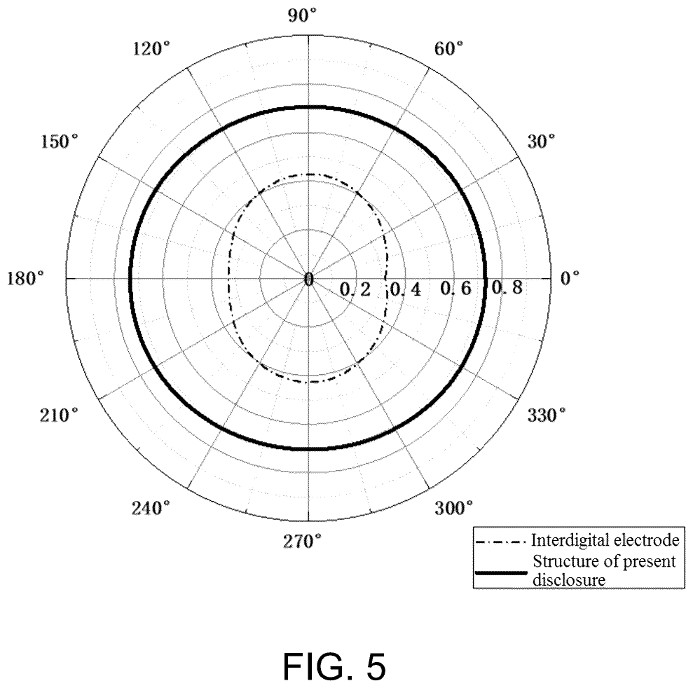

FIG. 5 is a curve chart of light absorptivity of semiconductor layers of the photoelectric detector structure for non-polarized light provided in the present disclosure and of an interdigital electrode structure changing with polarization directions.

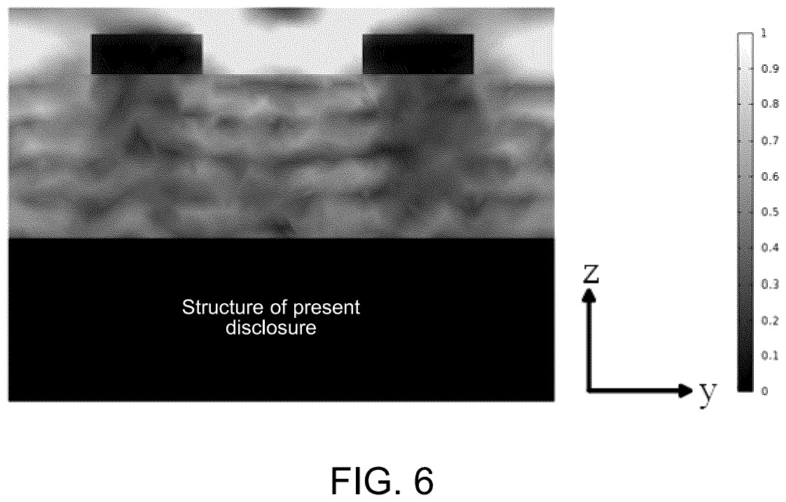

FIG. 6 is an electric field section schematic diagram of the unit structure in the photoelectric detector structure for non-polarized light provided in the present disclosure.

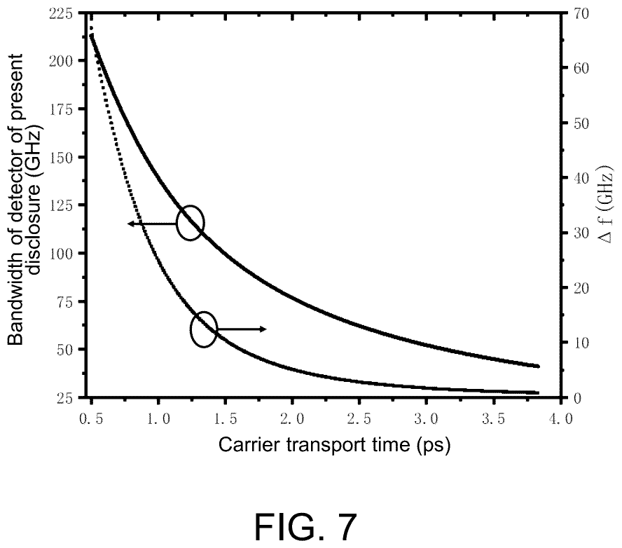

FIG. 7 shows the influence on the bandwidth of the photoelectric detector structure for non-polarized light provided in the present disclosure with carrier transport time, and the influence between a bandwidth difference under different capacitance of an active region of the detector and the carrier transport time.

The photoelectric detector structure for non-polarized light in the present disclosure is described in combination with FIG. 1, FIG. 2, FIG. 3, FIG. 4, FIG. 5, FIG. 6 and FIG. 7.

It can be seen from the above embodiment that a circular electrode structure adopted by the circular interdigital array electrode structure provided in the present disclosure enables the semiconductor layer to maintain certain absorption efficiency for the incident light in different polarization directions, a specific circular structure cycle is obtained through simulation, and under the action of a light field, a metal-semiconductor surface generates local field enhancement, thereby increasing the photoelectric conversion efficiency of the detector; the adjacent rows of the circular interdigital array electrode structure are in contact with the positive and negative electrodes respectively, and for the staggered structure, the carrier transport distance can be shorten by shortening the distances between the circular structures in the same row, thereby increasing the carrier transport bandwidth of the detector; and the circular interdigital array electrode can reduce the area between the positive and negative electrodes under the minimum transport distance, thereby reducing the capacitance of the active region of the detector under the same area of the active region, avoiding the problem of capacitance rise caused by the shortening of the distance, and increasing the RC bandwidth of the detector. Thus, the bandwidth of the detector is increased.

The carrier transport distance can be shorten by shortening the distances between the circular structures in the same row, and the distances between the adjacent circular structures are designed to achieve plasmon resonance enhancement of adjacent circles at the specific wavelength.

In this embodiment, a semiconductor material may be indium gallium arsenide (InGaAs) or gallium arsenide (GaAs). The semiconductor material such as GaAs, InGaAs and the like has the characteristics of short carrier lifetime, high mobility, large resistivity and coverage of communication frequency bands, and thus is used as the semiconductor layer of the photoelectric detector.

In this embodiment, FIG. 1 is the central section schematic diagram of the unit structure in the photoelectric detector structure for non-polarized light provided according to the exemplary embodiment.

Specifically, the photoelectric detection response wavelength designed in this embodiment is C-band. A thickness b of the substrate is generally greater than 50 μm, a thickness c of the semiconductor layer is set to be 1-3 μm, and a thickness h1 of the electrode layer is 200-270 nm; and an inner circle diameter w of each of the circular electrodes is 0.4-0.5 μm, and a difference r between an outer circle radius and an inner circle radius of each of the circular electrodes is 0.65-0.7 μm (that is, a wall thickness of each circle is 0.65-0.7 μm).

Preferably, 1550-nm InGaAs being used as the semiconductor layer is taken as an example, the used material for the electrode layer is Au, the used material for the substrate is InP, the used material for the anti-reflection layer is Si₃N₄, in the parameters, a=3.34 μm, c=1 μm, d=0.5 μm, h1=0.25 μm, h2=0.164 μm, w=0.98 μm, r=0.68 μm, and it is selected that the simulation incident light wavelength lambda=1550 nm.

FIG. 5 shows a curve of light absorptivity of a semiconductor layer of the photoelectric detector structure for non-polarized light provided according to the exemplary embodiment and a curve of light absorptivity of a semiconductor layer of the interdigital electrode structure for incident light at different polarization angles. When the polarization angle of the incident light is changed, the light absorption of the semiconductor layer is as shown in FIG. 5. Compared with the interdigital electrode structure, the structure of the present disclosure achieves that the absorptivity for the incident light in various directions is 70% or above, thereby greatly enhancing the absorption efficiency of the detector for the incident light in the different polarization directions, and increasing the light utilization rate.

FIG. 6 is the section electric field schematic diagram of the unit structure in the photoelectric detector structure for non-polarized light provided according to the exemplary embodiment. It can be seen from the drawing that compared with the interdigital electrode structure, in the structure, the local electric field inside the circles is greatly enhanced. This is because when the incident light irradiates the metal nano circular structure, conduction band free electrons on the metal surface perform collective motion to enable a surface electron cloud to deviate from atomic nuclei. Then a curved surface of the metal structure applies an effective restoring force to the free electrons undergoing collective motion, resulting in collective oscillation of the electrons near the atomic nuclei, generating the localized surface plasmon resonance (LSPR) phenomenon, causing the light field to be localized on the circular electrode-semiconductor interface, and generating the strong field enhancement effect.

Compared with a photoelectric detector of the interdigital electrode structure, the bandwidth advantage of the detector structure of the present disclosure is shown. During the capacitance simulation, the minimum transport distances between the positive and negative electrodes are the same, the electrode digital lengths are the same, the capacitance values of the two structures are obtained, the capacitance value of the interdigital electrode structure is 19.41 fF, the capacitance value of the detector structure of the present disclosure is 11.11 fF, and the capacitance of the photoelectric detector structure for non-polarized light is about 40% less than that of the traditional interdigital electrode.

The detector bandwidths under the different structures are calculated as per the formula, the change in the bandwidth increase value of the photoelectric detector for non-polarized light compared with that of the interdigital electrode with the carrier transport time is obtained, at the carrier transport time of 0.6 ps, the corresponding increase amount of the bandwidth is Δf=55 GHz. FIG. 7 shows the influence on the bandwidth of the photoelectric detector structure for non-polarized light provided in the present disclosure with the carrier transport time, and the influence between the bandwidth difference Δf of two structures and the carrier transport time.

According to absorption spectra for the incident light at the different polarization angles and the section electric field enhancement diagram of the photoelectric detector structure for non-polarized light, it can be seen from the results that the designed structure greatly improves the absorption efficiency of the semiconductor layer for the light, avoids the reduction of the RC bandwidth while shortening the carrier transport distance, and achieves the purposes of improving the conversion efficiency of the detector and increasing the bandwidth.

The embodiments are exhaustively listed. Any modification, equivalent replacement or improvement made within the spirit and principles of the present disclosure should fall within the scope of protection of the claims of the present disclosure.

What is claimed is:

1. A circular interdigital array plasmon electrode photoelectric detector suitable for non-polarized light, comprising: a substrate, a semiconductor layer, an electrode layer, and an anti-reflection layer, wherein the electrode layer comprises a circular interdigital array electrode and positive and negative electrodes on left side and right side; and the circular interdigital array electrode comprises circular electrodes and circular electrode connecting wires.

2. The circular interdigital array plasmon electrode photoelectric detector suitable for non-polarized light according to claim 1, wherein the circular electrodes of the circular interdigital array electrode are electrically connected to the positive and negative electrodes on the left side and the right side through the circular electrode connecting wires, and each row of the circular electrodes have reverse polarity to polarity of adjacent rows of the circular electrodes; and
the electrode layer is in ohmic contact with the semiconductor layer, and the circular interdigital array electrode meets plasmon resonance conditions.

3. A circular interdigital array plasmon electrode photoelectric detector suitable for non-polarized light, comprising: a substrate, a semiconductor layer, an electrode layer, and an anti-reflection layer, wherein the electrode layer comprises a circular interdigital array electrode and positive and negative electrodes on left side and right side; the circular interdigital array electrode comprises circular electrodes and circular electrode connecting wires; the circular electrodes of the circular interdigital array electrode are connected through the circular electrode connecting wires and are placed between the positive and negative electrodes;
wherein InGaAs with a response wavelength of 1550 nm serves as the semiconductor layer, a material of the electrode layer is Au, a material of the substrate is InP, and a material of the anti-reflection layer is Si₃N₄; a thickness of the substrate is greater than 50 μm, a thickness of the semiconductor layer is set to be 1 μm-3 μm, and a thickness of the electrode layer is 200 nm-270 nm; and an inner circle diameter w of each of the circular electrodes is 0.4 μm-0.5 μm, and a difference between an outer circle radius and an inner circle radius of each of the circular electrodes is 0.65 μm-0.7 μm.

4. The circular interdigital array plasmon electrode photoelectric detector suitable for non-polarized light according to claim 1, wherein the circular electrodes of the circular interdigital array electrode are connected through the circular electrode connecting wires and are placed between the positive and negative electrodes; and a circular electrode array is classified into a staggered distribution type or an aligned distribution type according to different arrangement manners.

5. The circular interdigital array plasmon electrode photoelectric detector suitable for non-polarized light according to claim 1, wherein the electrode layer is in ohmic contact or Schottky contact with the semiconductor layer; and under an action of an incident light field, free electrons on surfaces of metal electrodes of the circular interdigital array electrode are excited, and when plasmon resonance conditions are met, local electric field enhancement is generated around the metal electrodes, absorption efficiency of the semiconductor layer for the incident light is increased, and responsivity of the circular interdigital array plasmon electrode photoelectric detector is improved.

6. The circular interdigital array plasmon electrode photoelectric detector suitable for non-polarized light according to claim 1, wherein the circular electrodes of the circular interdigital array electrode are electrically connected to the positive and negative electrodes on the left side and the right side through the circular electrode connecting wires, each row of the circular electrodes have reverse polarity to polarity of adjacent rows of the circular electrodes, and when incident light having different polarization directions irradiates the circular interdigital array plasmon electrode photoelectric detector, absorptivity of the semiconductor layer remains stable.

7. The circular interdigital array plasmon electrode photoelectric detector suitable for non-polarized light according to claim 1, wherein for a staggered distribution type structure, minimum distances between any circle and adjacent circles around are equal to each other, and distances between the adjacent circles are reduced to shorten a transport distance and increase a carrier transport bandwidth of the detector; and for an aligned distribution type structure, the circles are arranged in a regular rectangular array, and distances between every two adjacent rows are reduced to shorten the transport distance and increase the transport bandwidth.

8. The circular interdigital array plasmon electrode photoelectric detector suitable for non-polarized light according to claim 1, wherein a material of the electrode layer is Ti, Al, Ni, Ge, Au, or Ag, or an alloy of Ti, Al, Ni, Ge, Au and Ag.

9. The circular interdigital array plasmon electrode photoelectric detector suitable for non-polarized light according to claim 1, wherein a material of the semiconductor layer GaAs, InGaAs, an InGaAs/InAlAs superlattice material, or ErAs:In(Al)GaAs.

10. The circular interdigital array plasmon electrode photoelectric detector suitable for non-polarized light according to claim 1, wherein a material of the anti-reflection film is SiNx or SiOx.

11. A preparation method for a circular interdigital array plasmon electrode photoelectric detector suitable for non-polarized light, comprising the following steps:
step 1: growing an epitaxial layer on a temporary substrate by using a metal-organic chemical vapor deposition or molecular beam epitaxy method;
step 2: performing photoetching, primary metal evaporation and metal stripping on a surface of the epitaxial layer to form a circular array electrode, electrode connecting wires, and positive and negative electrodes on left side and right side;
step 3: performing photoetching and etching on the structure to form a mesa structure, thereby obtaining a mesa semiconductor epitaxial layer, wherein an upper surface of the semiconductor epitaxial layer is covered with a metal electrode layer obtained in the step 2; and
step 4: performing photoetching and metal evaporation to form coplanar waveguide electrodes in contact with the positive and negative electrodes on the left side and the right side, thereby forming an electric connection for wire bonding during subsequent packaging.
